(19) United States
(12) Patent Application Publication
(10) Pub. No.: US 2014/0015126 A1
(43) Pub. Date: Jan. 16, 2014

(54) SEMICONDUCTOR PACKAGE AND STACKED SEMICONDUCTOR PACKAGE USING THE SAME

(71) Applicant: SK HYNIX INC., Icheon-si (KR)

(72) Inventor: Ju Heon YANG, Seoul (KR)

(73) Assignee: SK hynix Inc., Icheon-si (KR)

(21) Appl. No.: 13/670,188

(22) Filed: Nov. 6, 2012

(30) Foreign Application Priority Data
Jul. 10, 2012 (KR) 10-2012-0074876

(51) Int. Cl. H01L 23/485

(52) U.S. Cl. 257/737; 257/E23.021

(57) ABSTRACT

A semiconductor package including a semiconductor chip having a front surface and a rear surface which faces away from the front surface, pads disposed over the front surface of the semiconductor chip, and bumps formed over the pads, and each having a T-shaped configuration or defining an inverted T-shaped space.

### CROSS-REFERENCE TO RELATED APPLICATIONS

The present application claims priority to Korean Patent Application Number 10-2012-0074876 filed in the Korean Intellectual Property Office on Jul. 10, 2012, which is incorporated herein by reference in its entirety.

### BACKGROUND

1. Technical Field

The present invention generally relates to a semiconductor package and a stacked semiconductor package using the same, and more particularly, to a semiconductor package which can prevent the occurrence of a junction fail between bumps due to a junction pressure and a stacked semiconductor package using the same.

2. Related Art

Recently, as electronic appliances trend toward miniaturization and slim thickness, a flip chip technology is gaining popularity. The flip chip technology refers to a technology in which bumps may be formed on bonding pads of a semiconductor chip and the semiconductor chip is mounted to an outside circuit by the medium of junction of the bumps, without using additional connection means such as metal leads or bonding wires. The junction of the bumps includes junction between the bumps and an outside and junction between the bumps.

Main factors to be considered in the junction of the bumps are heat and pressure (hereinafter, referred to as ‘junction pressure’) applied when joining the bumps. In the case where the junction pressure is too low, problems may be caused in that poor junction may result between the bumps and the manufacturing yield of a semiconductor package may be reduced. Conversely, in the case where the junction pressure is too high, problems may be caused in that a physical damage such as a crack or chipping may be applied to a semiconductor chip and thus the manufacturing yield of the semiconductor package may be reduced.

### BRIEF SUMMARY

Various embodiments are generally directed to a semiconductor package which can prevent the occurrence of a junction fail between bumps due to a junction pressure, and a stacked semiconductor package using the same.

In an embodiment, a semiconductor package includes: a semiconductor chip having a front surface and a rear surface which faces away from the front surface; pads disposed over the front surface of the semiconductor chip; and bumps formed over the pads, and each having a T-shaped configuration or defining an inverted T-shaped space.

The pads may include bonding pads or redistribution pads.

Each bump having the T-shaped configuration may include: a first vertical member disposed over a middle portion of each pad; and a first upper end member disposed over the first vertical member.

The first upper end member may have the same width as the pad.

The first upper end member may have a width larger than the first vertical member.

Each bump defining the inverted T-shaped space may include: a second vertical member disposed over peripheral portions of each pad; and a second upper end member disposed over the second vertical member and defined with an opening through a middle portion thereof.

The second upper end member defined with the opening through the middle portion thereof may have the same width as the pad.

The semiconductor package may further include a substrate having bond fingers which are joined with the bumps.

The bond fingers may define an inverted T-shaped space or have a T-shaped configuration, such that the bumps having the T-shaped configuration or defining the inverted T-shaped space are configured for being slidingly joined with the bond fingers defining the inverted T-shaped space or having the T-shaped configuration.

In an embodiment, a stacked semiconductor package includes: a first semiconductor package including a semiconductor chip having a front surface and a rear surface which faces away from the front surface, pads disposed over the front surface of the semiconductor chip, first bumps formed over the pads and each having a T-shaped configuration, and second bumps formed over the rear surface of the semiconductor chip and each defining an inverted T-shaped space with an opening through an upper middle portion thereof to allow the first bump to be inserted into the inverted T-shaped space; one or more second semiconductor packages each having the same shape as the first semiconductor package and stacked over the first semiconductor package; and a third semiconductor package stacked over a second semiconductor package positioned uppermost among the stacked second semiconductor packages, and having first bumps, wherein the second bumps of the first semiconductor package and the first bumps of a lowermost second semiconductor package are configured to be slidingly joined with each other, and the second bumps of the uppermost second semiconductor package and the first bumps of the third semiconductor package are configured to be slidingly joined with each other.

The pads may include bonding pads or redistribution pads.

Each first bump may include: a first vertical member disposed over a middle portion of each pad; and a first upper end member disposed over the first vertical member.

The first upper end member may have the same width as the pad.

The first upper end member may have a width larger than the first vertical member.

Each second bump may include: a lower end member disposed on the rear surface of the semiconductor chip to correspond to each first bump; a second vertical member disposed over peripheral portions of the lower end member; and a second upper end member disposed over the second vertical member and defined with an opening through a middle portion thereof.

The second upper end member defined with the opening through the middle portion thereof may have the same width as the lower end member.

The stacked semiconductor package may further include underfill members filled in a space between the stacked first and second semiconductor packages and a space between the stacked second and third semiconductor packages.

The stacked semiconductor package may further include a structural body supporting the stacked first, second and third semiconductor packages, and having on one surface thereof connection electrodes configured to be slidingly joined with the first bumps of the first semiconductor package positioned lowermost.

The structural body may include any one of a printed circuit board, an interposer and a fourth semiconductor package.

The stacked semiconductor package may further include: a molding member formed to substantially cover the first, second and third semiconductor packages which are stacked on the one surface of the structural body; and external connection terminals disposed on the other surface of the structural body which faces away from the one surface.

The external connection terminals may include solder balls.

The stacked semiconductor package may further include through vias formed in the semiconductor chip to pass through the front surface and the rear surface, and having first ends which contact the pads and second ends which contact the second bumps.

Each pad may have a width larger than each through via.

Each second bump may include: a lower end member disposed over the second end of the through via; a second vertical member disposed over peripheral portions of the lower end member; and a second upper end member disposed over the second vertical member and defined with an opening through a middle portion thereof.

The lower end member may have a width larger than the through via.

The second upper end member defined with the opening through the middle portion thereof may have the same width as the lower end member.

### BRIEF DESCRIPTION OF THE DRAWINGS

FIG. 1 is a cross-sectional view illustrating a semiconductor package in accordance with an embodiment.

FIG. 2 is a cross-sectional view illustrating a semiconductor package in accordance with an embodiment.

FIG. 3A is a cross-sectional view illustrating the shape in which the bumps of FIG. 1 and first bond fingers are sliding-joined with each other.

FIG. 3B is a cross-sectional view illustrating the shape in which the bumps of FIG. 2 and second bond fingers are sliding-joined with each other.

FIG. 4 is a cross-sectional view illustrating a semiconductor package in accordance with an embodiment.

FIG. 5 is a cross-sectional view illustrating a stacked semiconductor package in accordance with an embodiment.

FIG. 6 is a cross-sectional view illustrating a stacked semiconductor package in accordance with an embodiment.

FIG. 7 is a perspective view illustrating an electronic apparatus having the semiconductor package according to various embodiments.

FIG. 8 is a system block diagram showing an electronic apparatus to which the semiconductor package according to the various embodiments is applied.

### DESCRIPTION OF SPECIFIC EMBODIMENTS

Hereafter, various embodiments will be described in detail with reference to the accompanying drawings. Additionally, the same reference numerals or the same reference designators may denote the same elements throughout the specification.

It is to be understood herein that the drawings are not necessarily to scale and in some instances proportions may have been exaggerated in order to more clearly depict certain features of the invention.

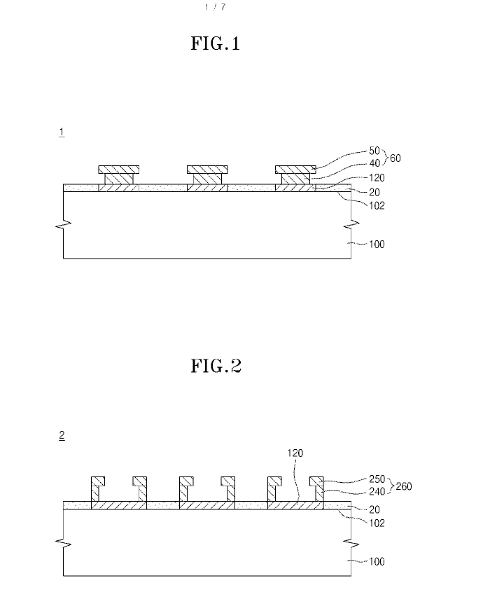

FIG. 1 is a cross-sectional view illustrating a semiconductor package in accordance with an embodiment, and FIG. 2 is a cross-sectional view illustrating a semiconductor package in accordance with an embodiment.

Referring to FIG. 1, a semiconductor package 1 in accordance with an embodiment (hereinafter, referred to as “the semiconductor package 1”) may include a semiconductor chip 100, pads 120 and first bumps 60. The semiconductor package 1 further may include a front surface insulation layer 20 which may be formed in such a way as to expose the pads 120.

The semiconductor chip 100 has, for example, a rectangular hexahedral shape, and possesses a front surface 102. While not shown, the semiconductor chip 100 may be understood as having a circuit unit formed therein. The circuit unit may include circuits which operate by receiving external power and signals, for example, a data storage unit for storing data and a data processing unit for processing data.

The pads 120 may be understood as, for example, bonding pads. In this case, the pads 120 may be disposed on the front surface 102 of the semiconductor chip 100 and may be electrically connected with the circuits which may be formed in the semiconductor chip 100. Additionally, the pads 120 may also be understood as redistribution pads. In this case, while not shown, the pads 120 may constitute portions of redistribution lines, and may be disposed not only on the front surface 102 of the semiconductor chip 100 but also on the surface which faces away from the front surface 102.

The first bumps 60 may be formed on the pads 120 and may be electrically connected with the pads 120, and each has a T-shaped configuration when viewed from a cross-section. For example, each first bump 60 may include a first vertical member 40 which may be disposed on the center portion of each pad 120 and a first upper end member 50 which may be disposed on the first vertical member 40.

The first upper end member 50 as the upper part of the T-shaped configuration has substantially the same size as each pad 120, and may be disposed over and substantially parallel to each pad 120. The first vertical member 40 vertically connects each pad 120 with the first upper end member 50. Each pad 120 and the first upper end member 50 may substantially have a quadrangular or circular shape when viewed from the top.

Referring to FIG. 2, a semiconductor package 2 in accordance with another embodiment (hereinafter, referred to as “another semiconductor package 2”) may include a semiconductor chip 100, pads 120, and second bumps 260. Another semiconductor package 2 further may include a front surface 102 and a front surface insulation layer 20 which may be formed in such a way as to expose the pads 120.

The semiconductor chip 100 and the pads 120 of another semiconductor package 2 have substantially the same configurations of the semiconductor chip 100 and the pads 120 of the semiconductor package 1.

The second bumps 260 may be formed on the pads 120 and may be electrically connected with the pads 120, and each defines an inverted T-shaped space in cooperation with each pad 120 when viewed from a cross-section. For example, each second bump 260 may have a second vertical member 240 which may be disposed on the peripheral portions of each pad 120 and a second upper end member 250 which may be disposed on the second vertical member 240 and is defined with an opening through the middle portion thereof, while each pad 120 serves as a lower end member.

The second vertical member 240 may contact the peripheral portions of each pad 120 and may be formed in a column-like shape on the peripheral portions of each pad 120 when viewed from a cross-section. The second upper end member 250 may be formed on the second vertical member 240 substantially parallel to the pad 120 in such a way as to be defined with the opening through the middle portion thereof.

The second vertical member 240 and the second upper end member 250 define an open part in at least one direction. For example, when the pad 120 is formed into substantially the quadrangular shape, the second vertical member 240 may be formed on two oppositely facing peripheral portions of each pad 120 or on three peripheral portions of each pad 120 including the two oppositely facing peripheral portions and any one peripheral portion connecting the two oppositely facing peripheral portions with each other, and the second upper end member 250 may contact the second vertical member 240, such that the first vertical member 40 and the first upper end member 50 of the first bump 60 may be slidingly inserted through the open part which may be defined by the second vertical member 240 and the second upper end member 250.

The semiconductor package 1 and another semiconductor package 2 may be stacked upon each other. That is to say, another semiconductor package 2 may be stacked on the semiconductor package 1, or the semiconductor package 1 may be stacked on another semiconductor package 2.

In the case where another semiconductor package 2 is stacked on the semiconductor package 1, the first bumps 60 of the semiconductor package 1 may be inserted into the inverted T-shaped spaces of the second bumps 260 of another semiconductor package 2 to fill the inverted T-shaped spaces of the second bumps 260 of another semiconductor package 2, such that the bumps 60 and 260 may be engaged with each other, that is, may be slidingly joined with each other. In this way, the semiconductor package 1 and another semiconductor package 2 may be joined with each other. When the sliding junction is implemented, junction between the bumps 60 and 260 may be completed in this state or may be reinforced by applying heat. In other words, if the melting point of a substance used to form the bumps 60 and 260 is low, the junction strength between the bumps 60 and 260 may be increased by applying heat through a reflow process.

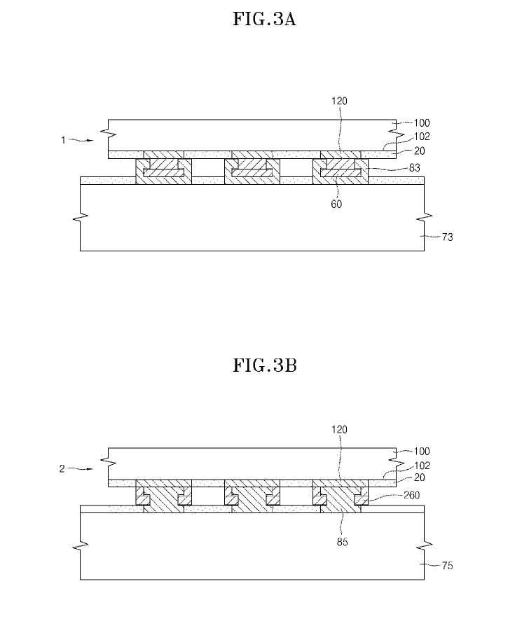

Referring to FIG. 3A, the semiconductor package 1 may be stacked on a first substrate 73 which may have first bond fingers 83. Each first bond finger 83 may have a cross-section which defines an inverted T-shaped space and may be open at the upper middle portion thereof, to allow each first bump 60 to be slidingly inserted into the inverted T-shaped space to be joined with the first bond finger 83.

Referring to FIG. 3B, another semiconductor package 2 may be stacked on a second substrate 75 which may have second bond fingers 85. Each second bond finger 85 may have a T-shaped configuration to allow each second bump 260 to be engaged with the T-shaped configuration of the second bond finger 85 to be slidingly joined with the second bond finger 85.

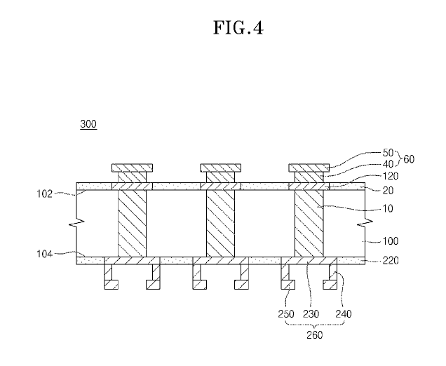

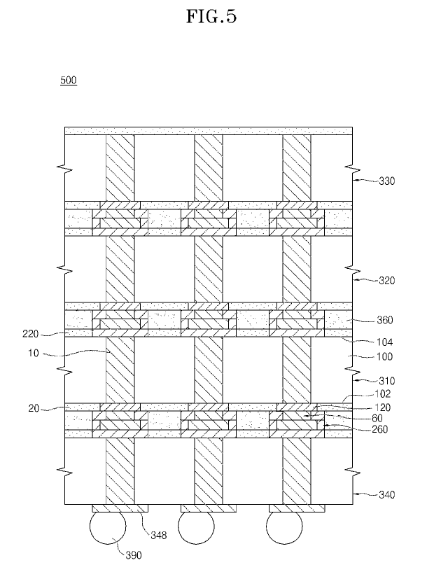

FIG. 4 is a cross-sectional view illustrating a semiconductor package in accordance with an embodiment.

Referring to FIG. 4, a semiconductor package 300 in accordance with an embodiment may include a semiconductor chip 100, through vias 10, first bumps 60, and second bumps 260.

The semiconductor chip 100 has a front surface 102 and a rear surface 104 which faces away from the front surface 102.

The semiconductor chip 100 may include a plurality of pads 120 which may be disposed on the front surface 102. Each pad 120 may have a width larger than each through via 10. The plurality of pads 120 may be arranged in one row or two rows on the middle portion of the front surface 102 of the semiconductor chip 100. Unlike this, the plurality of pads 120 may be arranged in one row or two rows on at least one of one peripheral portion and an opposite peripheral portion of the front surface 102, or may be arranged in one row or two rows along the peripheral portions of the front surface 102.

While not shown, the semiconductor chip 100 may include a circuit block formed therein. The circuit block may include circuits which operate by externally receiving power and signals, for example, a data storage unit for storing data and a data processing unit for processing data.

In succession, the through vias 10 may be formed to pass through the front surface 102 and the rear surface 104 of the semiconductor chip 100, and have first ends which may be disposed on the front surface 102 and second ends which may be disposed on the rear surface 104. The through vias 10 may be electrically connected with the circuit block.

The through vias 10 may be electrically connected with the pads 120 which may be disposed on the front surface 102 of the semiconductor chip 100, in one-to-one correspondence. To this end, the through vias 10 may be formed to pass through corresponding pads 120 such that the first ends of the through vias 10 may be directly connected electrically with the corresponding pads 120. Additionally, the through vias 10 may be formed to pass through portions of the semiconductor chip 100 which are adjacent to corresponding pads 120 such that the first ends of the through vias 10 may be electrically connected with the corresponding pads 120 by redistribution lines and the likes.

The first bumps 60 may be formed on portions of the pads 120 and each may have a T-shaped configuration when viewed from a cross-section. Additionally, each first bump 60 may include a first vertical member 40 which may be disposed on the center portion of each pad 120 and a first upper end member 50 which may be disposed on the first vertical member 40. The first upper end member 50 as the upper part of the T-shaped configuration may have substantially the same size as each pad 120, and may be disposed over and substantially parallel to each pad 120. The first vertical member 40 may be arranged on the extension line of each through via 10, may have substantially the same width as the through via 10, and vertically may connect each pad 120 with the first upper end member 50. Each pad 120 and the first upper end member 50 may have a quadrangular or circular shape when viewed from the top.

The semiconductor package 300 in accordance with an embodiment further may include a front surface insulation layer 20 which may be formed on the front surface 102 of the semiconductor chip 100. The front surface insulation layer 20 may be formed between adjacent pads 120 on the front surface 102 of the semiconductor chip 100. According to this fact, the first vertical members 40 and the first upper end members 50 of the first bumps 60 and one surfaces of the pads 120 brought into contact with the first vertical members 40 may be exposed out of the front surface insulation layer 20.

The second bumps 260 may be formed on the second ends of the through vias 10 which may be disposed on the rear surface 104 of the semiconductor chip 100, and each has a cross-section which defines an inverted T-shaped space and may be open at the upper middle portion thereof. The open portion of each second bump 260 may be over the extension line of each through via 10.

Additionally, each second bump 260 may include a lower end member 230 which may be disposed on each through via 10, a second vertical member 240 which may be disposed on peripheral portions of the lower end member 230 and a second upper end member 250 which may be disposed on the second vertical member 240 and may be defined with an opening through the middle portion thereof. The opening defined in the second upper end member 250 may have a width the same as or larger than the first vertical member 40 of the first bump 60, such that the first vertical member 40 can be inserted through the opening.

The lower end member 230, which defines the bottom of the inverted T-shaped space, contacts the through via 10 and may have a width larger than the through via 10. Further, the lower end member 230 has a width larger than the pad 120. The second vertical member 240 contacts the peripheral portions of the lower end member 230 and may be formed in a column-like shape on the peripheral portions of the lower end member 230 when viewed from a cross-section.

The second upper end member 250 may be formed on the second vertical member 240 substantially parallel to the lower end member 230 in such a way as to be defined with the opening through the middle portion thereof, that is, have the opening arranged on the extension line of the through via 10.

The lower end member 230 may have a quadrangular or circular shape when viewed from the top. The second vertical member 240 and the second upper end member 250 may define an open part in at least one direction. For example, when the lower end member 230 is formed into the quadrangular shape, the second vertical member 240 may be formed on two oppositely facing peripheral portions of each pad 120 or on three peripheral portions of each pad 120 including the two oppositely facing peripheral portions and any one peripheral portion connecting the two oppositely facing peripheral portions with each other, and the second upper end member 250 may contact the second vertical member 240, such that the first vertical member 40 and the first upper end member 50 of the first bump 60 may be slidingly inserted through the open part which may be defined by the second vertical member 240 and the second upper end member 250.

The semiconductor package 300 in accordance with an embodiment further may include a rear surface insulation layer 220 which may be formed on the rear surface 104 of the semiconductor chip 100.

The rear surface insulation layer 220 may be formed between adjacent lower end members 230 on the rear surface 104 of the semiconductor chip 100. According to this fact, the second vertical members 240 and the second upper end members 250 of the second bumps 260 and one surfaces of the lower end members 230 brought into contact with the second vertical members 240 may be exposed out of the rear surface insulation layer 220.

As is apparent from the above descriptions, in a semiconductor package according to the present invention, by forming first bumps 60 with a T-shaped configuration when viewed from a cross-section, on the front surface of a semiconductor chip of a downwardly positioned semiconductor package, and forming second bumps 260 with an inverted T-shaped opening when viewed from a cross-section, on the front surface of a semiconductor chip of an upwardly positioned semiconductor package, unit packages with the first bumps 60 and the second bumps 260 may be stacked not through heat pressing as in the conventional art but through sliding and application of heat.

Therefore, in the semiconductor package according to the present invention, because junction between bumps may be implemented even without applying a junction pressure, it is possible to prevent the occurrence of a junction fail due to the application of the junction pressure.

Hereafter, stacked semiconductor packages constructed using the above-described semiconductor packages according to various embodiments will be described.

FIG. 5 is a cross-sectional view illustrating a stacked semiconductor package in accordance with an embodiment.

Referring to FIG. 5, a stacked semiconductor package 500 in accordance with an embodiment may include a first semiconductor package 310 and at least one second semiconductor package 320. Also, the stacked semiconductor package 500 in accordance with an embodiment further may include an underfill member 360, such as an NCP (non-conductive paste) or an NCF (non-conductive film), which is filled in the space between the stacked semiconductor packages 310 and 320.

The first semiconductor package 310 may include a semiconductor chip 100, through vias 10, first bumps 60, and second bumps 260.

The semiconductor chip 100 has a front surface 102 and a rear surface 104 which faces away from the front surface 102. The semiconductor chip 100 may include a plurality of pads 120 as bonding pads, which may be disposed on the front surface 102. Each pad 120 may have a width larger than each through via 10. Further, while not shown, the semiconductor chip 100 may include a circuit block formed therein.

The through vias 10 may be formed to pass through the front surface 102 and the rear surface 104 of the semiconductor chip 100, and have first ends which may be disposed on the front surface 102 and second ends which may be disposed on the rear surface 104. The through vias 10 may be electrically connected with the circuit block.

The first bumps 60 may be formed on the pads 120 and each may have a T-shaped configuration when viewed from a cross-section. The second bumps 260 may be formed on the second ends of the through vias 10 and each defines an inverted T-shaped space with an opening through the upper middle portion thereof in cooperation with each pad 120 when viewed from a cross-section.

The first semiconductor package 310 further may include a front surface insulation layer 20 which may be formed on the front surface 102 of the semiconductor chip 100 to expose the pads 120 and a rear surface insulation layer 220 which may be formed on the rear surface 104 of the semiconductor chip 100 to expose the lower end members of the second bumps 260.

In succession, the at least one second semiconductor package 320 may be stacked on the first semiconductor package 310. In the present embodiment, one second semiconductor package 320 may be stacked. The second semiconductor package 320 has the same configuration as the first semiconductor package 310. In particular, the second semiconductor package 320 may be stacked on the first semiconductor package 310 such that the second bumps 260 of the second semiconductor package 320 may be slidingly joined with the first bumps 60 of the first semiconductor package 310. Namely, the first bumps 60 of the first semiconductor package 310 may be inserted into the inverted T-shaped spaces of the second bumps 260 of the second semiconductor package 320 to fill the inverted T-shaped spaces of the second bumps 260 of the second semiconductor package 320, such that the bumps 60 and 260 may be engaged with each other. In this way, the first semiconductor package 310 and the second semiconductor package 320 may be joined with each other.

When junction between the bumps 60 and 260 is implemented in the sliding type, the junction may be completed in this state or may be reinforced by applying heat. In other words, if the melting point of a substance used to form the bumps 60 and 260 is low, the junction strength between the bumps 60 and 260 may be increased by applying heat through a reflow process.

The through vias 10 of the stacked first and second semiconductor packages 310 and 320 may be electrically connected with each other through the junction between the first bumps 60 and the second bumps 260.

While not shown, at least two second semiconductor packages 320 may be stacked. In the case where at least two second semiconductor packages 320 are stacked, the first bumps of an upwardly positioned second semiconductor package may be electrically connected with the second bumps of a downwardly positioned semiconductor package.

The stacked semiconductor package 500 in accordance with the various embodiments further may include a third semiconductor package 330 which may be stacked on the second semiconductor package 320 or on a second semiconductor package 320 positioned uppermost among stacked second semiconductor packages 320. The third semiconductor package 330 may have substantially the same structure as the first and second semiconductor packages 310 and 320 except that second bumps may not be formed on the second ends of through vias 10.

That is to say, first bumps 60 of the third semiconductor package 330 may be inserted into the inverted T-shaped spaces of the second bumps 260 of the uppermost second semiconductor package 320 such that the bumps 60 and 260 are engaged with each other. In this way, the third semiconductor package 330 and the uppermost second semiconductor package 320 may be joined with each other.

The third semiconductor package 330 may include the same kind of semiconductor chip as the first and second semiconductor packages 310 and 320, or may include a different kind of semiconductor chip from the first and second semiconductor packages 310 and 320, for example, a driving chip.

The stacked semiconductor package 500 in accordance with the various embodiments further may include a structural body which may be disposed below the first semiconductor package 310.

The structural body may be a fourth semiconductor package 340 which may have through vias 10 as connection electrodes and second bumps 260. The fourth semiconductor package 340 may include a semiconductor chip 100 which has a front surface and a rear surface, the through vias 10 which may be formed to pass through the front surface and the rear surface and have first ends disposed on the front surface and second ends disposed on the rear surface, the second bumps 260 which may be formed on the second ends of the through vias 10, and redistribution lines 348 which may be formed on the front surface of the semiconductor chip 100 to be connected at one ends thereof with the first ends of the through vias 10. The fourth semiconductor package 340 may include the same kind of memory chip as the first, second and third semiconductor packages 310, 320, and 330, or may include a different kind of chip from the first, second and third semiconductor packages 310, 320, and 330.

While not shown, the structural body may be constituted by an interposer which has connection electrodes.

In succession, the stacked semiconductor package 500 in accordance with the various embodiments further may include external connection terminals 390 such as solder balls, which may be attached to the redistribution lines 348 of the fourth semiconductor package 340.

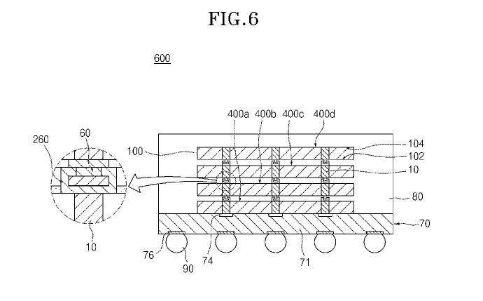

FIG. 6 is a cross-sectional view illustrating a stacked semiconductor package in accordance with an embodiment.

Referring to FIG. 6, a stacked semiconductor package 600 in accordance with an embodiment may include a plurality of semiconductor packages. In an embodiment, the stacked semiconductor package 600 may include four semiconductor packages 400a to 400d which are stacked upon one another.

The four semiconductor packages 400a to 400d may be stacked vertically in substantially one direction. Each of the semiconductor packages 400a to 400d may include a semiconductor chip 100, through vias 10, first bumps 60, and second bumps 260. In the four semiconductor packages 400a to 400d, the semiconductor package 400d positioned uppermost may not include the second bumps 260. Also, the semiconductor package 400a positioned lowermost may not include the first bumps 60.

The semiconductor chip 100 may have a front surface 102 and a rear surface 104 which faces away from the front surface 102. While not shown, the semiconductor chip 100 may include a circuit block formed therein. The through vias 10 may be formed to pass through the front surface 102 and the rear surface 104 of the semiconductor chip 100 and may be electrically connected with the circuit block.

Each first bump 60 has a T-shaped configuration when viewed from a cross-section. Each second bump 260 defines an inverted T-shaped space when viewed from a cross-section, and may be open at the upper middle portion thereof.

The stacked semiconductor package 600 in accordance with an embodiment may further include a structural body which may be disposed below the lowermost semiconductor package 400a. The structural body may be a printed circuit board 70 which may have connection electrodes such as bond fingers 74. While not shown, the structural body may be an interposer which has connection electrodes.

The printed circuit board 70 may include a body 71, the bond fingers 74, and ball lands 76.

The body 71 may have a plate-like shape, and the four stacked semiconductor packages 400a to 400d may be disposed on the upper surface of the body 71. The bond fingers 74 may be disposed on the upper surface of the body 71 and may be electrically connected with the through vias 10 of the lowermost positioned semiconductor package 400a. The ball lands 76 may be disposed on the lower surface of the body 71 and may be electrically connected with corresponding bond fingers 74.

The stacked semiconductor package 600 in accordance with an embodiment further may include a molding member 80 and mounting members 90.

The molding member 80 may substantially cover the four stacked semiconductor packages 400a to 400d and the upper surface of the printed circuit board 70. The molding member 80 may protect the fourth stacked semiconductor packages 400a to 400d from externally applied shock and/or vibration.

The mounting members 90 may be disposed on the other surface of the structural body facing away from one surface of the structural body on which the four stacked semiconductor packages 400a to 400d may be disposed, and may serve as means for mounting the stacked semiconductor package 600 to an external circuit. The mounting members 90 may include, for example, solder balls, and are respectively formed on the ball lands 76.

While not shown, the stacked semiconductor package 600 in accordance with an embodiment may further include underfill members such as NCPs and NCFs, which may be filled in spaces between the four stacked semiconductor packages 400a to 400d and between the lowermost positioned semiconductor package 400a and the substrate 70.

The through vias 10 of the four stacked semiconductor packages 400a to 400d may be electrically connected with one another through junction of the first bumps 60 and the second bumps 260.

The junction between the first bumps 60 and the second bumps 260 may be implemented in a sliding type.

In other words, the first bumps 60 may be inserted into the inverted T-shaped spaces of the second bumps 260 to fill the inverted T-shaped spaces of the second bumps 260, such that the first and second bumps 60 and 260 may be engaged with each other. In this way, the four stacked semiconductor packages 400a to 400d may be joined with one other.

As is apparent from the above descriptions, in the stacked semiconductor package according to the various embodiments, the junction may be implemented not by applying a junction pressure as in the conventional art but in the sliding type, to stack semiconductor chips without applying a junction pressure.

Additionally, in order to allow the junction between bumps to be implemented in the sliding type, first bumps 60, which have a T-shaped configuration when viewed from a cross-section and may be formed on the front surface of a semiconductor chip, and second bumps 260, which have an inverted T-shaped opening when viewed from a cross-section and may be formed on the rear surface of the semiconductor chip, may be used. As a consequence, because the junction between bumps may be implemented even without applying a junction pressure, it is possible to prevent the occurrence of a junction fail due to the application of the junction pressure.

The semiconductor package according to the various embodiments may be applied to various package modules.

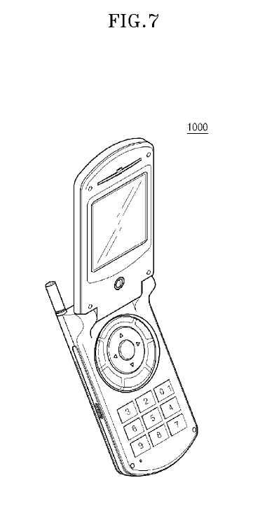

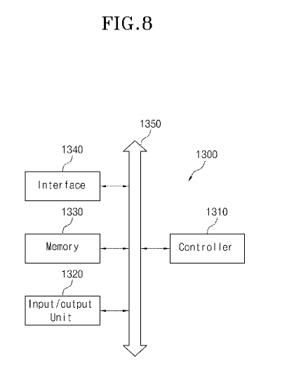

FIG. 7 is a perspective view illustrating an electronic apparatus having the semiconductor package according to the various embodiments.

Referring to FIG. 7, the semiconductor package according to the various embodiments may be applied to an electronic apparatus 1000 such as a portable phone. Since the semiconductor package according to the various embodiments is excellent in terms of size reduction and an electrical characteristic, advantages are provided in accomplishing light weight, thinness, compactness, and miniaturization of the electronic apparatus 1000 which realizes various functions.

The electronic apparatus 1000 is not limited to the portable phone shown in FIG. 7, and may include various electronic appliances, for example, such as a mobile electronic appliance, a laptop computer, a notebook computer, a portable multimedia player (PMP), an MP3 player, a camcorder, a web tablet, a wireless phone, a navigator, a personal digital assistant (PDA), and so forth.

FIG. 8 is a block diagram showing, for example, an electronic apparatus which may include the semiconductor package according to the various embodiments.

Referring to FIG. 8, an electronic system 1300 may include a controller 1310, an input/output unit 1320, and a memory 1330. The controller 1310, the input/output unit 1320 and the memory 1330 may be coupled with one another through a bus 1350.

The bus 1350 serves as a path through which data move. For example, the controller 1310 may include at least any one of at least one microprocessor, at least one digital signal processor, at least one microcontroller, and logic devices capable of performing the same functions as these components.

The controller 1310 and the memory 1330 may include the semiconductor device according to the embodiments of the present invention. The input/output unit 1320 may include at least one selected among a keypad, a keyboard, a display device, and so forth. The memory 1330 is a device for storing data.

The memory 1330 may store data and/or commands to be executed by the controller 1310, and the likes. The memory 1330 may include a volatile memory device and/or a nonvolatile memory device. Otherwise, the memory 1330 may be constituted by a flash memory. For example, a flash memory to which the technology of the present invention is applied may be mounted to an information processing system such as a mobile terminal or a desk top computer. The flash memory may be constituted by a solid state drive (SSD). In this case, the electronic system 1300 may stably store a large amount of data in a flash memory system.

The electronic system 1300 may further include an interface 1340 configured to transmit and receive data to and from a communication network. The interface 1340 may be a wired or wireless type. For example, the interface 1340 may include an antenna or a wired or wireless transceiver. Further, while not shown, a person skilled in the art will readily appreciate that the electronic system 1300 may be additionally provided with an application chipset, a camera image processor (CIS), an input/output unit, etc.

Although specific embodiments of the present invention have been described for illustrative purposes, those skilled in the art will appreciate that various modifications, additions and substitutions are possible, without departing from the scope and the spirit of the invention as disclosed in the accompanying claims.

What is claimed is:

1. A semiconductor package comprising:
a semiconductor chip having a front surface and a rear surface which faces away from the front surface;
pads disposed over the front surface of the semiconductor chip; and
bumps formed over the pads, and each having a T-shaped configuration or defining an inverted T-shaped space.

2. The semiconductor package according to claim 1, wherein the pads comprise bonding pads or redistribution pads.

3. The semiconductor package according to claim 1, wherein each bump having the T-shaped configuration comprises:
a first vertical member disposed over a middle portion of each pad; and
is a first upper end member disposed over the first vertical member.

4. The semiconductor package according to claim 3, wherein the first upper end member has a width larger than the first vertical member.

5. The semiconductor package according to claim 1, wherein each bump defining the inverted T-shaped space comprises:
a second vertical member disposed over peripheral portions of each pad; and
a second upper end member disposed over the second vertical member and defined with an opening through a middle portion thereof.

6. The semiconductor package according to claim 1, further comprising:
a substrate having bond fingers which are joined with the bumps.

7. The semiconductor package according to claim 6, wherein the bond fingers define an inverted T-shaped space or have a T-shaped configuration, such that the bumps having the T-shaped configuration or defining the inverted T-shaped space are configured for being slidingly joined with the bond fingers defining the inverted T-shaped space or having the T-shaped configuration.

8. A stacked semiconductor package comprising:
a first semiconductor package including a semiconductor chip is having a front surface and a rear surface which faces away from the front surface, pads disposed over the front surface of the semiconductor chip, first bumps formed over the pads and each having a T-shaped configuration, and second bumps formed over the rear surface of the semiconductor chip and each defining an inverted T-shaped space with an opening through an upper middle portion thereof to allow the first bump to be inserted into the inverted T-shaped space;
one or more second semiconductor packages each having substantially the same shape as the first semiconductor package and stacked over the first semiconductor package; and
a third semiconductor package stacked over a second semiconductor package positioned uppermost among the stacked second semiconductor packages, and having first bumps,
wherein the second bumps of the first semiconductor package and the first bumps of a lowermost second semiconductor package are configured to be slidingly joined with each other, and the second bumps of the uppermost second semiconductor package and the first bumps of the third semiconductor package are configured to be slidingly joined with each other.

9. The stacked semiconductor package according to claim 8, wherein the pads comprise bonding pads or redistribution pads.

10. The stacked semiconductor package according to claim 8, wherein each first bump comprises:
is a first vertical member disposed over a middle portion of each pad; and
a first upper end member disposed over the first vertical member.

11. The stacked semiconductor package according to claim 10, wherein the first upper end member has a width larger than the first vertical member.

12. The stacked semiconductor package according to claim 8, wherein each second bump comprises:
a lower end member disposed on the rear surface of the semiconductor chip to correspond to each first bump;
a second vertical member disposed over peripheral portions of the lower end member; and
a second upper end member disposed over the second vertical member and defined with an opening through a middle portion thereof.

13. The stacked semiconductor package according to claim 8, further comprising:
underfill members filled in a space between the stacked first and second semiconductor packages and a space between the stacked second and third semiconductor packages.

14. The stacked semiconductor package according to claim 8, further comprising:
a structural body supporting the stacked first, second, and is third semiconductor packages, and having on one surface thereof connection electrodes configured to be slidingly joined with the first bumps of the first semiconductor package positioned lowermost.

15. The stacked semiconductor package according to claim 14, wherein the structural body comprises any one of a printed circuit board, an interposer, and a fourth semiconductor package.

16. The stacked semiconductor package according to claim 14, further comprising:
a molding member formed to substantially cover the first, second, and third semiconductor packages which are stacked on the one surface of the structural body; and
external connection terminals disposed on the other surface of the structural body which faces away from the one surface.

17. The stacked semiconductor package according to claim 8, further comprising:
through vias formed in the semiconductor chip to pass through the front surface and the rear surface, and having first ends which contact the pads and second ends which contact the second bumps.

18. The stacked semiconductor package according to claim 17, wherein each pad has a width larger than each through via.

19. The stacked semiconductor package according to claim 17, wherein each second bump comprises:
a lower end member disposed over the second end of the through via;
a second vertical member disposed over peripheral portions of the lower end member; and
a second upper end member disposed over the second vertical member and defined with an opening through a middle portion thereof.

20. The stacked semiconductor package according to claim 19, wherein the lower end member has a width larger than the through via.
